(19) United States
(12) Patent Application Publication
(10) Pub. No.: US 2007/0128861 A1
(43) Pub. Date: Jun. 7, 2007

(54) CVD apparatus for depositing polysilicon

(76) Inventors: Myoung Soo Kim, Yongin-si (KR); Han Ki Kim, Yongin-si (KR); Seok Heon Jeong, Yongin-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/405,091

(22) Filed: Apr. 17, 2006

(30) Foreign Application Priority Data
Dec. 5, 2005 (KR) 10-2005-39926

(51) Int. Cl. H01L 21/84; H01L 21/44; C23C 16/00

(52) U.S. Cl. 438/680; 438/164; 118/715

(57) ABSTRACT

Disclosed is a CVD apparatus for depositing polysilicon without a separate following annealing process, the CVD apparatus comprising: a chamber to form a thin film on a substrate; a showerhead placed in an upper part of the chamber to inject reaction gas onto the substrate; a distributor formed with distributing holes to uniformly distribute the reaction gas; a catalyst hot wire unit to heat and dissolve the reaction gas injected through the distributing holes of the distributor; a chuck on which the substrate is mounted; a discharging hole to discharge the reaction gas; and a shielding wall provided as a lateral wall of the chamber and formed with a heater to suppress particle generation. With this configuration, the particle generation is minimized and thus the yield is enhanced. Also, the thin film has good crystallinity, and decreased hydrogen content.

### CROSS-REFERENCE TO RELATED APPLICATIONS

This application claims the benefit of Korean Patent Application No. 10-2005-0039926, filed on May 12, 2005, in the Korean Intellectual Property Office, the disclosure of which is incorporated herein by reference.

### BACKGROUND OF THE INVENTION

1. Field of the Invention

The present embodiments relate to a chemical vapor deposition (CVD) apparatus for depositing polysilicon, and more particularly, to a CVD apparatus for depositing polysilicon without a separate following annealing process.

2. Description of the Related Art

In general, when silicon (Si) is deposited on a glass substrate, silicon is either formed as polysilicon (P-Si) or amorphous silicon (A-Si).

FIGS. 1A and 1B show structures of polysilicon and amorphous silicon, respectively. Silicon is generally formed as polysilicon at a temperature of more than about 600° C. or as amorphous silicon at a temperature of less than about 600° C.

In comparison with amorphous silicon, polysilicon is structurally stable, and the electrical, chemical and mechanical properties of polysilicon are good.

Further, FIGS. 2A and 2B show driver connection structures according to silicon properties in a thin film transistor (TFT). In the case of using amorphous silicon, a printed circuit board (PCB) or an integrated circuit (IC) provided as a driver should be separately connected to the TFT as shown in FIG. 2B. On the other hand, when polysilicon is used, the driver can be provided integrally with the TFT as shown in FIG. 2A, so that the size of the driver can be reduced.

FIG. 3 illustrates a TFT structure for driving a display device using polysilicon, in which a polysilicon region is shown by a dotted line. The polysilicon region is the region through which on/off operations of the TFT are determined, e.g., through which an electron and a hole are transferred. In other words, the polysilicon region is a involved in TFT performance. A polysilicon TFT generally has a more stable structure as compared with an amorphous silicon TFT. Therefore, the polysilicon TFT has advantages in that it is fastly operated due to high field effect mobility (cm/Vs) and can be driven by low voltage. Further, the structural stability of the polysilicon causes uniform electric property to be obtained when the TFT is fabricated, so that an additional compensation circuit is not needed.

As described above, the device using polysilicon has many advantages. However, a temperature of more than about 600° C. is required to form the polysilicon, and thus a glass substrate cannot maintain its shape at this temperature. Therefore, a new method is needed to apply polysilicon to a display device employing glass as the substrate.

Recently, a low temperature polysilicon (LTPS) method has been widely used to form a TFT at low temperature. In the LTPS method, an amorphous silicon layer is deposited on a substrate at a relatively low temperature of less than about 450° C. and then annealed using laser and heat, so that the layer of amorphous silicon is transformed into polysilicon. That is, the LTPS method includes dehydrogenating and leaser(heat)-annealing processes after forming amorphous silicon layer.

However, such conventional LTPS method has disadvantages in that the processes are complicated and much time is taken to perform the processes. Further, the conventional LTPS method requires expensive equipment including a laser, thereby increasing production cost of the display device and lowering the competitiveness thereof. Nevertheless, most of display manufacturers employ the LTPS method. Accordingly, a new method of forming polysilicon without using a laser is needed.

As an example of methods using no laser, there is a sequential lateral solidification (SLS) method, a metal induced crystallization (MIC) method, a super grain silicon (SGS) method, etc. However, these methods also require another processes in addition to the depositing process, so there are many problems in applying these methods to mass production.

Other methods of depositing silicon include a physical vapor deposition (PVD) method, and a chemical vapor deposition (CVD) method. The CVD method has been widely used because it has good step coverage characteristic in forming a thin film. In the CVD method, gaseous raw materials are dissolved and then reacted, thereby depositing the thin film. Source gas of silicon used in the CVD method includes SiH₄, Si₂H₆, SiH₂Cl₂, etc. Generally, most of source gas is used with H₂, N₂, etc.

Among the CVD methods for depositing silicon, the plasma enhanced chemical vapor deposition (PECVD) method and a thermal CVD method are generally used. In the PECVD, the source gas is dissolved using plasma, thereby forming a thin film on the substrate. In the thermal CVD, the source gas is dissolved using heat, thereby forming a thin film on the substrate.

Because the PECVD method uses plasma, it can be applied to a display, a solar cell, a sensor, etc. which are used at a low temperature like the glass substrate. On the other hand, the thermal CVD method is performed at a relatively high temperature, so that it is widely used in a field employing Si or a metal substrate, etc.

When silicon is deposited by the PECVD method, the source gas is deposited as SiHn based on the following [Reaction formula 1] onto the substrates and formed as the thin film.
SiH₄+H₂→SiHn⁺+H₂↑ [Reaction formula 1]

The silicon atom deposited as SiHn⁺ onto the substrate is combined with another neighbor silicon atom, thereby causing the silicon atoms to be formed into polysilicon. Thus, the thin film formed by this method not only has bad crystallinity but also has increased hydrogen content. The combination of Si—H in the thin film is easily separated by external energy, which deteriorates the reliability of the device. In particular, this problem has a big effect on an organic light emitting diode (OLED), a field emission display (FED), a solar cell or the like, which uses the optical characteristic of material thereof.

As an example of an apparatus of forming a thin film on the substrate, there is a catalytic CVD apparatus that dissolves reaction gas to be deposited using a catalyst.

FIGS. 4 and 5 are sectional views illustrating a conventional catalytic CVD apparatus using a catalyst.

As shown in FIG. 4, the CVD apparatus includes a showerhead 12 provided in an upper part of the chamber 10 and injecting reaction gas on a substrate 18; a distributor to uniformly distribute the reaction gas; a catalyst hot wire unit 16 to generate high temperature heat to heat and dissolve the injected reaction gas; a chuck 19 on which the substrate 18 is mounted; and a discharging hole 11 to discharge the reaction gas.

The distributor 14 is shaped like a plate and formed with a plurality of distributing holes 14a arranged at regular intervals. Thus, the reaction gas injected through the showerhead 12 passes through the distributing holes 14a and is injected with uniform distributing density.

The catalyst hot wire unit 16 includes a hot wire 16a that is heated to have high temperature by electric power. The hot wire 16a is generally made of tungsten. Referring to FIG. 4, the catalyst hot wire 16 is installed inside the chamber 10.

Thus, in the conventional catalytic CVD apparatus, the reaction gas is introduced from the showerhead 12 into the chamber 10 via the distributing holes 14a of the distributor 14, so that the reaction gas is injected onto the substrate 18, having uniform distributing density.

The reaction gas passing through the distributor 14 is converted into ions or radicals while passing through the high temperature hot wire 16a of the catalyst hot wire unit 16.

The reaction gas passing through the catalyst hot wire unit 16 is completely converted into ions or radicals, and the ion or the radical is chemically and physically reacted on the substrate 18, so that deposition is performed on the substrate 18.

Meanwhile, FIG. 5 illustrates a CVD apparatus of which a catalyst hot wire unit and a showerhead are integrated. Such a CVD apparatus includes a showerhead 22 provided in an upper portion of a chamber 20 which injects reaction gas on a substrate 28; a distributor 24 to uniformly distribute the reaction gas; a catalyst hot wire unit 26 to generate high temperature heat to heat and dissolve the injected reaction gas; a chuck 29 on which the substrate 28 is mounted; and a discharging hole 21 to discharge the reaction gas.

The catalyst hot wire unit 26 is mounted to the showerhead 22, and includes a hot wire 26a placed under distributing holes 24a of the distributor 24.

In the CVD apparatus with this configuration shown in FIG. 5, the reaction gas passing through the distributor 24 is converted into ions or radicals by the high temperature catalyst hot wire unit 26, and the ion or the radical is chemically and physically reacted on the substrate 28, so that deposition is performed on the substrate 28.

However, such a conventional catalytic CVD apparatus using the catalyst has three problems: catalyst deterioration, particle generation, and a limited process parameter due to reaction between the catalyst and the reaction gas.

First, the catalyst is deteriorated as follows.

When the catalyst hot wire is heated to a high temperature, a bending region or a power receiving region thereof has a relatively low temperature. In the case that the process is performed in this state, the catalyst in these regions is reacted with the reaction gas and creates tungsten silicide (WSi₂). The created tungsten silicide (WSi₂) is different in electrical characteristic from tungsten, and thus causes local heat generation when the temperature of the catalyst increases. Further, the created tungsten silicide (WSi₂) is harder than tungsten, and thus causes a thin film to be easily broken due to external impact, thereby decreasing the reliability of the system.

Second, the particle is generated as follows.

The source gas (SiH₄) is deposited on all surfaces of the chamber as well as the substrate. In the case that adhesion between the wall of the chamber and the silicon thin film is weak, the deposited silicon thin film is changed into particles as the process is performed, thereby having an effect on the process. The particle is generated by reacting with H₂ gas contained in process gas. To prevent the particle from generating, the adhesion should be enhanced. For example, the adhesion can be enhanced by heating the wall of the chamber at a temperature of more than 100° C., usually at a temperature of more than 300° C. However, in the conventional CVD apparatus, the wall of the chamber is in contact with the outside, so that it is impossible to heat the wall at such high temperature.

Third, the process parameter is limited as follows.

In the case of the CVD apparatus using the catalyst, the quality and the configuration of the catalyst are significant. That is, the uniformity and the characteristic of the thin film can vary according to the distance between the showerhead and the catalyst. However, it is impossible to adjust the distance between the showerhead and the catalyst in such CVD apparatus, thereby limiting the characteristic improvement of the thin film.

In the CVD apparatus shown in FIG. 5, the catalyst hot wire unit is integrated with the showerhead and control components are needed to supply power to the showerhead and the catalyst. However, this configuration is complicated to manufacture.

Further, to change the configuration of the catalyst, there is a problem of changing the showerhead. Therefore, it is difficult to apply such limitation of the characteristic improvement to a large-sized display requiring a thin film that should have good characteristics and good thickness uniformity.

### SUMMARY OF THE INVENTION

Accordingly, it is an aspect of the present embodiments to provide a CVD apparatus for using a glass substrate and depositing polysilicon without a separate subsequent annealing process.

Another aspect of the present embodiments is to provide a CVD apparatus in which catalyst deterioration is prevented, particle generation is minimized, and process parameter is not limited.

Still another aspect of the present embodiments is to provide a CVD apparatus for forming a high quality silicon thin film with low hydrogen content.

The foregoing and/or other aspects of the present embodiments are achieved by providing a CVD apparatus comprising: a chamber having walls and configured to form a thin film on a substrate; a showerhead placed in an upper part of the chamber and configured to inject reaction gas onto the substrate; a distributor formed with distributing holes placed downstream of the reaction gas injected into the chamber from the showerhead and interposed between the showerhead and the substrate configured to uniformly distribute the reaction gas; a catalyst hot wire unit to heat and dissolve the reaction gas injected through the distributing holes of the distributor; a substrate; a chuck, positioned in the chamber downstream of the showerhead and the catalyst hotwire unit, on which the substrate is mounted; one or more discharging holes to discharge the reaction gas; and a shielding wall provided as a lateral wall of the chamber and formed with a heater to suppress particle generation.

According to another aspect of the embodiments, the catalyst hot wire unit comprises a gas channel through which purging gas is introduced, which allows the reaction gas and the purging gas to be separately introduced into the chamber. Here, the gas channel is laterally formed to supply the purging gas to a coupling portion of a catalyst hot wire of the catalyst hot wire unit.

According to an aspect of the embodiments, the CVD apparatus further comprises a passage to supply the purge gas between an inner wall of the chamber and the shielding wall, wherein the passage is formed transversely to the showerhead and allows the purging gas to flow through along the inner wall of the chamber and be discharged through the discharging hole.

According to an aspect of the embodiments, the heater comprises a hot wire inserted inside the shielding wall.

According to an aspect of the embodiments, the purging gas includes one or more of H₂, Ar, N₂ and He.

Other aspects of the present embodiments are achieved by providing a CVD apparatus comprising: a chamber having walls and configured to form a thin film on a substrate; a showerhead placed in an upper part of the chamber and configured to inject reaction gas onto the substrate; a distributor formed with distributing holes placed downstream of the reaction gas injected into the chamber from the showerhead and interposed between the showerhead and the substrate and configured to uniformly distribute the reaction gas; a catalyst hot wire unit to heat and dissolve the reaction gas injected through the distributing holes of the distributor; a chuck, positioned in the chamber downstream of the showerhead and the catalyst hotwire unit, on which the substrate is mounted; one or more discharging holes to discharge the reaction gas; and a gas channel provided in the catalyst hot wire unit which allows the reaction gas and the purging gas to be separately introduced into the chamber.

### BRIEF DESCRIPTION OF THE DRAWINGS

These and/or other aspects and advantages of the embodiments will become apparent and more readily appreciated from the following description of the preferred embodiments, taken in conjunction with the accompanying drawings of which:

FIGS. 1A and 1B shows structures of polysilicon and amorphous silicon, respectively;

FIGS. 2A and 2B shows driver connection structures according to silicon properties in a TFT;

FIG. 3 is sectional view of a TFT structure for driving a display device using polysilicon;

FIG. 4 is a sectional view of a conventional CVD apparatus using a catalyst;

FIG. 5 is a sectional view of another conventional CVD apparatus using a catalyst;

FIG. 6 is a sectional view of a CVD apparatus according to an embodiment; and

FIG. 7 is a sectional view illustrating a gas flow in the CVD apparatus according to an embodiment.

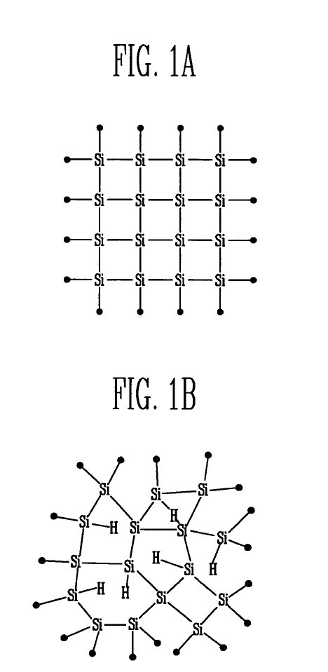

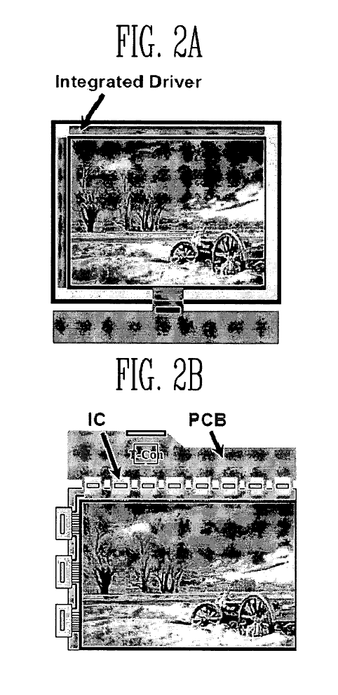

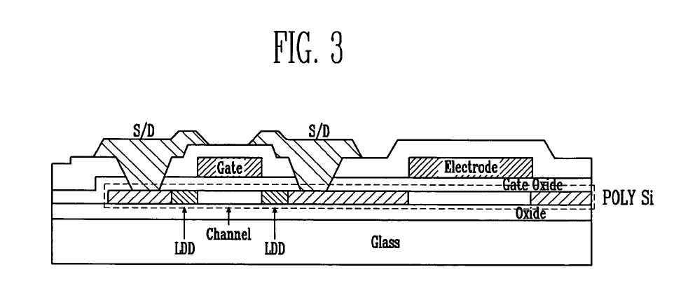

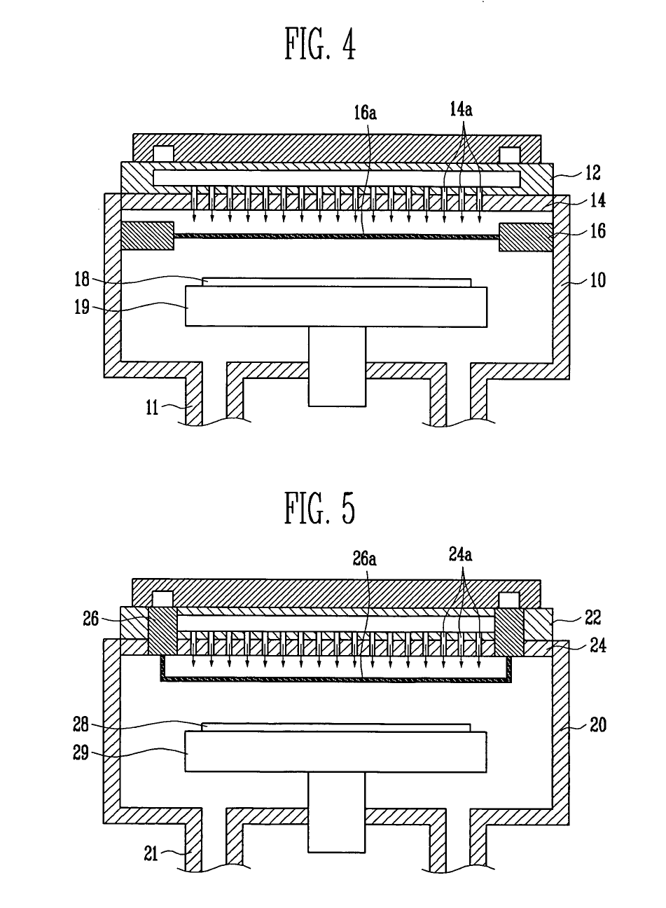

### DETAILED DESCRIPTION OF PREFERRED EMBODIMENTS

Hereinafter, preferable embodiments will be described with reference to the accompanying drawings, wherein the preferred embodiments are provided to be readily understood by those skilled in the art.

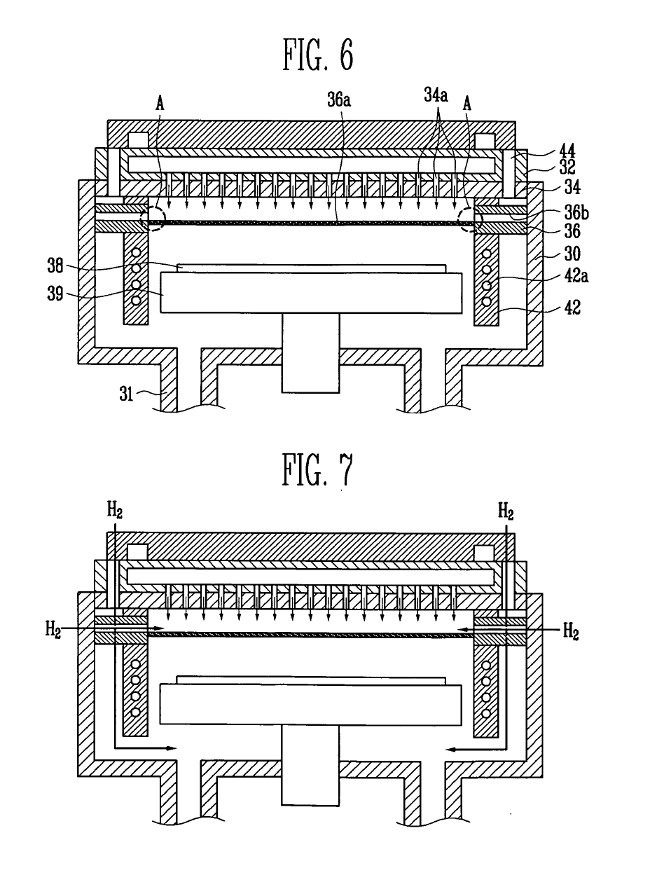

FIG. 6 is a sectional view of a CVD apparatus according to an embodiment. The CVD apparatus according to an embodiment includes a chamber 30 in which to form a thin film on a substrate 38; a showerhead 32 placed in an upper part of the chamber 30 to inject reaction gas onto the substrate 38; a distributor 34 formed with distributing holes 34a to uniformly distribute the reaction gas; a catalyst hot wire unit 36 to heat the reaction gas injected through the distributing holes 34a of the distributor 34 and convert the reaction gas into ions or radicals; a chuck 39 on which the substrate 38 is mounted; and a discharging hole 31 to discharge the reaction gas, which has the same configuration as the conventional CVD apparatus.

Here, the CVD apparatus according to one embodiment further comprises an shielding wall 42 provided as a lateral wall of the chamber 30 and suppressing particle generation.

The shielding wall 42 prevents particles from being generated from a silicon thin film deposited on the inner wall of the chamber 30. To suppress the particle generation, the shielding wall 42 is heated at a temperature of more than about 100° C., preferably, at a temperature of more than about 300° C.

According to an embodiment, the shielding wall 42 is provided with a high temperature heater. As an example of the heater, a high temperature hot wire 42a can be inserted inside the shielding wall 42.

The hot wire 42a is heated when electric power is supplied thereto. According to an embodiment, the hot wire 42a can make the temperature of the shielding wall 42 be increased to a temperature of about 100° C. through about 400° C., thereby minimizing the particle generation in a process.

That is, when converted source gas, such as SiH₄, for example, is deposited, the source gas is deposited on an inner surface of the shielding wall 42 because the shielding wall 42 is provided inside the chamber 30. In some embodiments, because the shielding wall 42 is being heated by the hot wire 42a at a temperature of about 400° C., adhesion between the shielding wall 42 and the deposited silicon thin film is decreased, thereby preventing the silicon thin film from being changed into particles. Thus, particle generation is minimized.

Meanwhile, the catalyst hot wire unit 36 is formed with a gas channel 36b through which purging gas is introduced.

The gas channel 36b can be laterally formed in the catalyst hot wire unit 36 so as to supply the purging gas to a coupling portion (see “A” in FIG. 6) of a catalyst hot wire 36a.

Here, the purging gas includes, for example, one or more of H₂, Ar, N₂, He, etc. In one embodiment, H₂ is employed as the purging gas, but the embodiments are not limited to H₂. Alternatively, another gas can be used as the purging gas.

According to an embodiment, the reaction gas is injected through the distributing holes 34a and the purging gas is injected through the gas channel 36b, so that the reaction gas and the purging gas are separately and independently injected into the inside of the chamber 30 (see FIG. 7).

This structure prevents the reaction gas and the purging gas from being diluted and having a negative affect on the process. Further, the purging gas is injected from the lateral sides of the catalyst hot wire unit 36 into the chamber 30, so that the reaction gas is prevented from being reacted in a low temperature portion, e.g., the coupling portion (see “A” in FIG. 6) of the catalyst hot wire 36a of the catalyst hot wire unit 36, thereby preventing the catalyst from deterioration.

Further, a passage 44 is formed between the inner wall of the chamber 30 and the shielding wall 42 so as to supply the purging gas.

The passage 44 can be formed transversely to the showerhead 32, so that the purging gas injected through the passage 44 flows along the inner wall of the chamber 30 and is discharged through the discharging hole 31. Further, the passage 44 communicates with the distributor 34. Also, the passage 44 has a structure that allows the purging gas to pass through the catalyst hot wire unit 36 and flow along the inner wall of the chamber 30.

Thus, when the purging gas injected from the passage 44 flows along the inner wall of the chamber 30, the non-heated wall of the chamber 30 prevents the thin film from being deposited thereon, thereby preventing particle generation.

With this configuration, the CVD apparatus according to an embodiment operates as follows.

The reaction gas is introduced from the showerhead 32 into the chamber 30 through the distributing holes 34a of the distributor 34.

The reaction gas passing through the distributor 34 is converted into ions or radicals by the high temperature catalyst hot wire 36a of the catalyst hot wire unit 36.

The reaction gas passing through the catalyst hot wire 36a is completely converted into ions or radicals. Here, the ion or the radical is chemically and physically reacted and then deposited on the substrate 38.

In the CVD apparatus according to a further embodiment, the shielding wall 42 installed inside the chamber 30 is controlled to have a substantially constant temperature, so that the adhesion of the silicon thin film deposited on the substrate by the process gas, for example, SiH₄, is improved. The improved adhesion of the silicon thin film deposited on the shielding wall 42 suppresses particle generation from the thin film due to the reaction and an etching effect in the process. Preferably, the shielding wall 42 installed inside the chamber 30 is controlled to have a substantially constant temperature of less than about 400° C.

This structure can overcome the limitation that the temperature of the wall of the chamber 30 bordered by the outside cannot increase to about 400° C.

Further, when cleaning the chamber 30, the temperature of the shielding wall 42 can be controlled to maximize the cleaning effectiveness.

In the CVD apparatus according to an embodiment using the catalyst, the reaction gas collides with the catalyst hot wire unit 36 heated at a high temperature, so that completely dissolved Si is deposited onto the substrate based on the following Reaction Formula 2.
SiH₄+H₂→SiHn⁺+H₂↑ Reaction Formula 2:

Thus, Si is easily combined with neighboring silicon atoms, so that the thin film has good crystallinity and has a decreased hydrogen content.

In comparison with the processes of the CVD apparatus according to an embodiment using the catalyst, the conventional LTPS method using the laser additionally includes the dehydrogenating process.

Such conventional LTPS method has disadvantages in that the processes are complicated and much time is taken to perform the processes. Further, the conventional LTPS method requires expensive equipment including a laser, and requires a CVD system for deposition and dehydrogenation. Thus, the convention LTPS method consumes much cost of investment and maintenance, so that the production cost of a device is increased, thereby lowering price competitiveness.

On the other hand, the CVD apparatus of the present embodiments using the catalyst can directly form polysilicon without additional equipments as shown in FIG. 6, thereby remarkably reducing the time and the cost of processing.

According to an embodiment, the processes are performed at a temperature of less than about 400° C., so that glass can be used as the substrate.

According to an embodiment, device fabricating technology is unique, so that polysilicon deposition technology and its deposition method are exclusive, thereby ensuring device competitiveness.

According to an embodiment, polysilicon can be formed without processes such as an annealing process even though glass is employed as the substrate.

Further, the catalyst is prevented from being deteriorated in the process, and the particle generation is minimized, thereby enhancing the yield.

Also, the resulting thin film has good crystallinity and decreased hydrogen content.

Additionally, the period between required preventive maintenance of the chamber is increased, thereby enhancing productivity.

While the present embodiments have been described in connection with certain exemplary embodiments, it is to be understood by those skilled in the art that the present embodiments are not limited to the disclosed embodiments, but, on the contrary, are intended to cover various modifications included within the sprit and scope of the appended claims and equivalents thereof.

What is claimed is:

1. A chemical vapor deposition apparatus comprising:
a chamber having walls;
a showerhead placed in an upper part of the chamber and configured to inject reaction gas onto a substrate;
a distributor formed with distributing holes placed downstream of the reaction gas injected into the chamber from the showerhead and interposed between the showerhead and the substrate;
a catalyst hot wire unit configured to heat and dissolve the reaction gas injected through the distributing holes of the distributor;
a chuck, positioned in the chamber downstream of the showerhead and the catalyst hotwire unit, on which the substrate is mounted;
wherein the chamber comprises one or more discharging holes positioned to discharge the reaction gas; and
a shielding wall provided as a lateral wall inside the chamber between the chamber walls and the chuck.

2. The chemical vapor deposition apparatus of claim 1 wherein the shielding wall comprises a heater configured to suppress particle generation.

3. The chemical vapor deposition apparatus according to claim 1, wherein the catalyst hot wire unit further comprises a gas channel through which purging gas is introduced to the chamber separately from reaction gas.

4. The chemical vapor deposition apparatus according to claim 3, wherein the gas channel is laterally formed to supply the purging gas to a coupling portion of a catalyst hot wire of the catalyst hot wire unit.

5. The chemical vapor deposition apparatus according to claim 1, further comprising a passage between an inner wall of the chamber and the shielding wall.

6. The chemical vapor deposition apparatus according to claim 5, wherein the passage is formed transversely to the showerhead and allows the purging gas to flow through along the inner wall of the chamber and be discharged through the discharging hole.

7. The chemical vapor deposition apparatus according to claim 3, further comprising a passage between an inner wall of the chamber and the shielding wall

8. The chemical vapor deposition apparatus according to claim 7, wherein the passage is formed transversely to the showerhead and allows the purging gas to flow through along the inner wall of the chamber and be discharged through the discharging hole.

9. The chemical vapor deposition apparatus according to claim 1, wherein the heater comprises a hot wire inserted inside the shielding wall.

10. The chemical vapor deposition apparatus according to claim 1, wherein the shielding wall is heated by the heater to a temperature from about 100° C. to about 400° C.

11. The chemical vapor deposition apparatus according to claim 7, wherein the shielding wall is heated by the heater to a temperature from about 100° C. to about 400° C.

12. The chemical vapor deposition apparatus according to claim 3, wherein the purging gas comprises one or more of H₂, Ar, N₂ and He.

13. A chemical vapor deposition apparatus comprising:
a chamber having walls;
a showerhead placed in an upper part of the chamber and configured to inject reaction gas onto a substrate;
a distributor formed with distributing holes placed downstream of the reaction gas injected into the chamber from the showerhead and interposed between the showerhead and the substrate;
a catalyst hot wire unit configured to heat and dissolve the reaction gas injected through the distributing holes of the distributor;
a chuck, positioned in the chamber downstream of the showerhead and catalyst hotwire unit, on which the substrate is mounted;
wherein the chamber comprises one or more discharging holes positioned to discharge the reaction gas; and
a gas channel provided in the catalyst hot wire unit which introduces purging gas into the chamber separately from the reaction gas.

14. The chemical vapor deposition apparatus according to claim 13, wherein the gas channel is laterally formed to supply the purging gas to a coupling portion of a catalyst hot wire of the catalyst hot wire unit.

15. The chemical vapor deposition apparatus according to claim 13, further comprising a passage to supply the purge gas between an inner wall of the chamber and a shielding wall.

16. The chemical vapor deposition apparatus according to claim 15, wherein the passage is formed transversely to the showerhead and allows the purging gas to flow through along the inner wall of the chamber and be discharged through the discharging hole.

17. The chemical vapor deposition apparatus according to claim 14, further comprising a passage to supply the purging gas between an inner wall of the chamber and a shielding wall.

18. The chemical vapor deposition apparatus according to claim 17, wherein the passage is formed transversely to the showerhead and allows the purging gas to flow through along the inner wall of the chamber and be discharged through the discharging hole.

19. The chemical vapor deposition apparatus according to claim 13, further comprising a shielding wall provided laterally to the chamber and formed with a heater.

20. The chemical vapor deposition apparatus according to claim 19, wherein the heater comprises a hot wire inserted inside the shielding wall.

21. The chemical vapor deposition apparatus according to claim 19, wherein the shielding wall is heated by the heater to a temperature from about 100° C. to about 400° C.

22. The chemical vapor deposition apparatus according to claim 20, wherein the shielding wall is heated by the heater to a temperature from about 100° C. to about 400° C.

23. The chemical vapor deposition apparatus according to claim 13, wherein the purging gas comprises one or more of H₂, Ar, N₂ and He.
